(19) United States
(12) Patent Application Publication
(10) Pub. No.: US 2010/0148992 A1
(43) Pub. Date: Jun. 17, 2010

(54) INPUT APPARATUS FOR ELECTRONIC DEVICE

(76) Inventor: Stuart Wittmann, Grand Forks, ND (US)

Correspondence Address: JAY M. SCHLOFF, 6960 Orchard Lake Road, Suite 315, West Bloomfield, MI, 48322, US

(21) Appl. No.: 12/332,411

(22) Filed: Dec. 11, 2008

(51) Int. Cl. H03K 17/94

(52) U.S. Cl. 341/20

(57) ABSTRACT

Disclosed is an input apparatus for an electronic device. The input apparatus includes an optical wireless pointing device and a receiver module. The optical wireless pointing device includes a finger sleeve, a first switch, a second switch, an optical means, a central processing unit, a transmitter and a battery. The finger sleeve is configured to accommodate a finger of a user. The optical means is configured to detect movement of the finger sleeve relative to an underlying surface. The central processing unit is configured to generate a spatial data based on the movement of the finger sleeve detected by the optical means. The transmitter is configured to wirelessly transmit the spatial data. The receiver module is adapted to receive the spatial data wirelessly transmitted by the transmitter and direct the spatial data to the electronic device.

### FIELD OF THE INVENTION

The present invention generally relates to a pointing device for an electronic device, and, more particularly, to a pointing device configured to be positionable on a finger of a user.

### BACKGROUND OF THE INVENTION

A pointing device, for example a computer mouse, is a human interface device configured to allow a user to input spatial data to a computer. The spatial data may be multidimensional and may be inputted to the computer continuously. The pointing device is configured to allow the user to control and provide data to various electronic devices including the computer, by moving the computer mouse across an underlying surface, such as mouse pad and the like. The pointing device may include plurality of switches or buttons disposed thereon. The pointing device movements are replicated on a screen of the electronic devices by movements of a cursor and other visual changes.

There are existing pointing devices, which are configured to allow the user to input the spatial data to the computer. These existing pointing devices have numerous limitations. For example, the existing pointing devices are not ergonomic in design. Further, the existing pointing devices are not capable of preventing tenderness and Carpel Tunnel Syndrome in a hand of a user. Furthermore, the existing pointing devices are not configured to be used on multiple underlying surfaces.

Accordingly, there exists a need for an input apparatus for an electronic device that is ergonomic in design. Further, there is a need for an input apparatus capable of preventing tenderness and Carpel Tunnel Syndrome in a hand of a user. Furthermore, there is a need for an input device capable of being used on multiple underlying surfaces.

### SUMMARY OF THE INVENTION

In view of the foregoing disadvantages inherent in the prior art, the general purpose of the present invention is to provide an input apparatus for an electronic device that is configured to include all the advantages of the prior art, and to overcome the drawbacks inherent therein.

Accordingly, an object of the present invention is to provide an input apparatus for an electronic device that is ergonomic in design.

Another object of the present invention is to for an input apparatus capable of preventing tenderness and Carpel Tunnel Syndrome in a hand of a user.

Yet another object of the present invention is to provide an input device capable of being used on multiple underlying surfaces.

In light of the above objects, an input apparatus for an electronic device is disclosed. The input apparatus includes an optical wireless pointing device and a receiver module. The optical wireless pointing device includes a finger sleeve, a first switch, a second switch, an optical means, a central processing unit, a transmitter and a battery. The finger sleeve is configured to accommodate a finger of a user. The finger sleeve is adapted to be moved relative to an underlying surface. The first switch is disposed on a bottom portion of the finger sleeve. The second switch is disposed on a side portion of the finger sleeve. The optical means is configured on the finger sleeve. The optical means is configured to detect movement of the finger sleeve relative to the underlying surface. The central processing unit is disposed on the finger sleeve. The central processing unit is electronically coupled to the first switch, the second switch and the optical means. The central processing unit configured to generate a spatial data based on the movement of the finger sleeve detected by the optical means. The transmitter is functionally coupled to the central processing unit. The transmitter is configured to wirelessly transmit the spatial data. The battery is disposed on the finger sleeve. The battery is functionally coupled to the first switch, the second switch, the optical means, the central processing unit and the transmitter. The receiver module is electronically coupled to the electronic device. The receiver module is adapted to receive the spatial data wirelessly transmitted by the transmitter and direct the spatial data to the electronic device.

This aspect together with other aspects of the present invention, along with the various features of novelty that characterize the present invention, are pointed out with particularity in the claims annexed hereto and form a part of this present invention. For a better understanding of the present invention, its operating advantages, and the specific objects attained by its uses, reference should be made to the accompanying drawings and descriptive matter in which there are illustrated exemplary embodiments of the present invention.

### BRIEF DESCRIPTION OF THE DRAWINGS

The advantages and features of the present invention will become better understood with reference to the following detailed description and claims taken in conjunction with the accompanying drawings, in which:

FIG. 1 illustrates a block diagram of an input apparatus for an electronic device, in accordance with an embodiment of the present invention;

FIG. 2A illustrates a top perspective view of an optical wireless pointing device of the input apparatus of FIG. 1, in accordance with an embodiment of the present invention;

FIG. 2B illustrates a bottom perspective view of an optical wireless pointing device of the input apparatus of FIG. 1, in accordance with an embodiment of the present invention;

FIG. 3 illustrates a perspective view of a finger sleeve of the optical wireless pointing device FIG. 2A and FIG. 2B, in accordance with another embodiment of the present invention; and

FIG. 4 illustrates a perspective view of the input device of the FIG. 1 in an operative position thereof, in accordance with another embodiment of the present invention.

Like reference numerals refer to like parts throughout the description of several views of the drawings.

### DETAILED DESCRIPTION OF THE INVENTION

The exemplary embodiments described herein detail for illustrative purposes are subject to many variations in structure and design. It should be emphasized, however, that the present invention is not limited to a particular input apparatus for an electronic device as shown and described. It is understood that various omissions and substitutions of equivalents are contemplated as circumstances may suggest or render expedient, but these are intended to cover the application or implementation without departing from the spirit or scope of the claims of the present invention.

The terms “first,” “second,” and the like, herein do not denote any order, quantity, or importance, but rather are used to distinguish one element from another, and the terms “a” and “an” herein do not denote a limitation of quantity, but rather denote the presence of at least one of the referenced item.

The present invention discloses an input apparatus for an electronic device. The electronic device may be a computer, a laptop, a palm top, a personal digital assistance, a video game and the like.

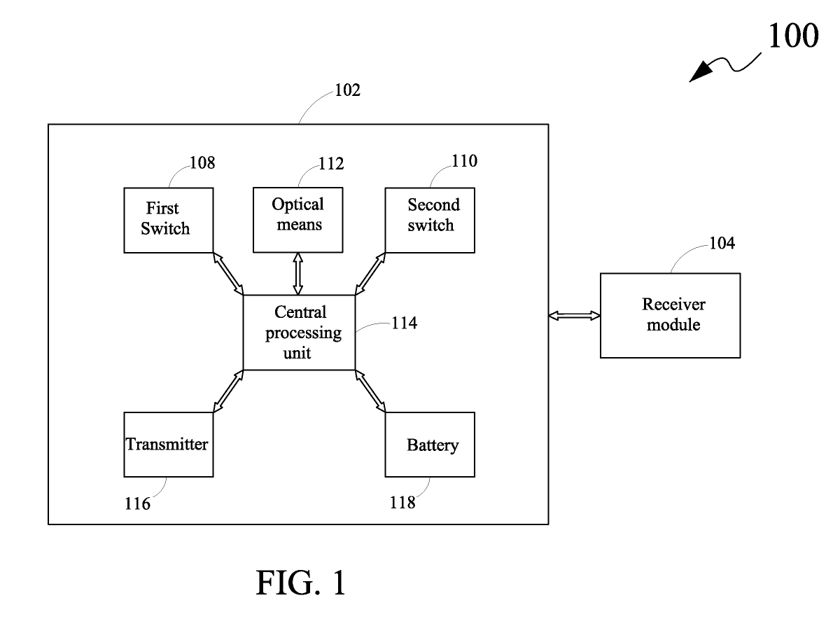

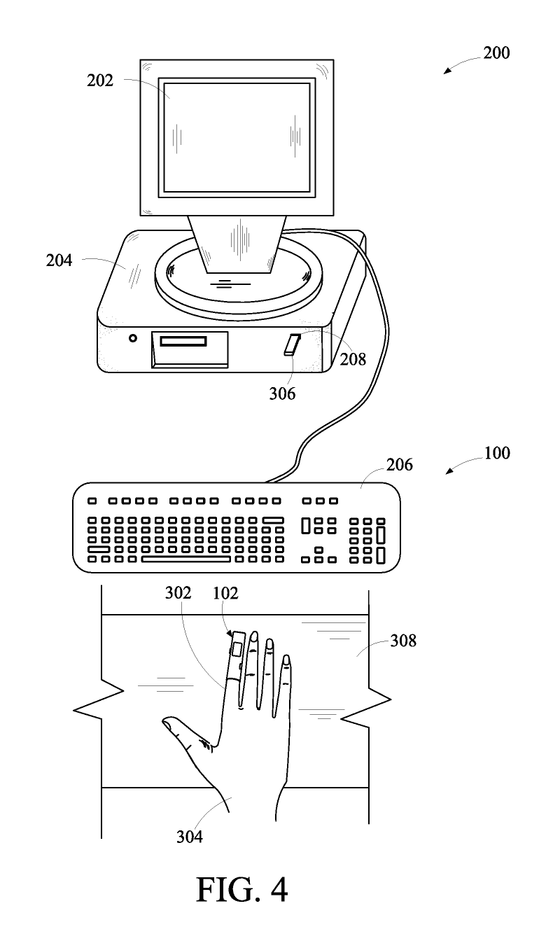

Referring to FIG. 1, a block diagram of an input apparatus 100 for an electronic device (described in conjunction with FIG. 4) is illustrated, in accordance with an embodiment of the present invention. The input apparatus 100 is configured to perform all functions performed by the conventional pointing device of the computer and to overcome the drawbacks inherent therein. The input apparatus 100 includes an optical wireless pointing device 102 and a receiver module 104. The optical wireless pointing device 102 is configured to receive a finger of a user (described in conjunction with FIG. 4). Further, the optical wireless pointing device 102 is configured to allow the user to input spatial data into the electronic device. The receiver module 104 is configured to be electronically coupled to the electronic device.

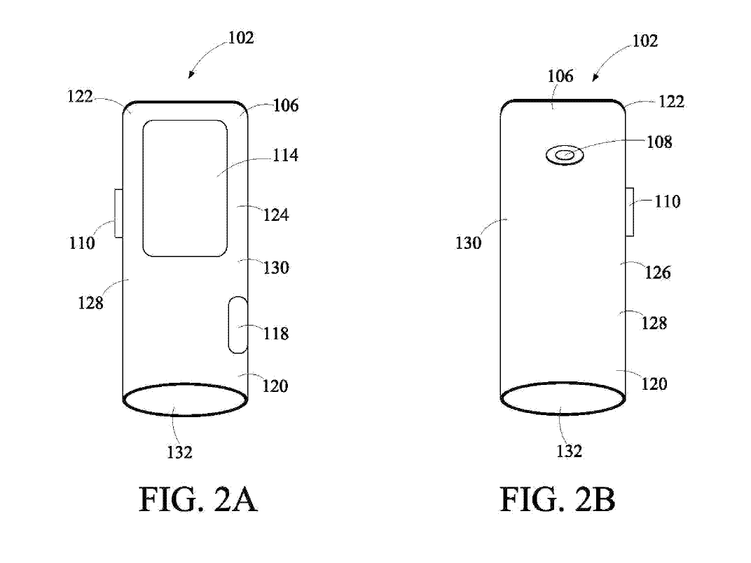

Now referring to FIG. 1, FIG. 2A and FIG. 2B, the optical wireless pointing device 102 is illustrated. The optical wireless pointing device 102 includes a finger sleeve 106, a first switch 108, a second switch 110, an optical means 112, a central processing unit 114, a transmitter 116 and a battery 118.

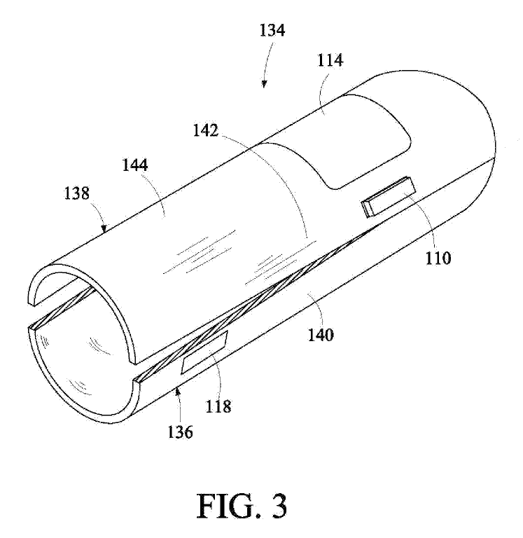

The finger sleeve 106 is configured to accommodate a finger of a user. Further, the finger sleeve 106 is adapted to be moved relative to an underlying surface (described in conjunction with FIG. 4). The finger sleeve 106 includes a first end portion 120, a second end portion 122, a top portion 124, a bottom portion 126, a first side portion 128 and a second side portion 130. The first end portion 120 of the finger sleeve 106 is configured to form an opening 132 for insertion of the finger of the user. The second end portion 122 of the finger sleeve 106 is configured to be close. More specifically, the finger sleeve 106 is configured to taper from the first end portion 120 to the second end portion 122 in a way such that the first end portion 120 may be circular in shape and the second end portion 122 may be substantially flat. In another embodiment of the present invention, the finger sleeve 106 may be configured to have a cylindrical shape, a cubical shape, or any other shape. Accordingly the present invention is not limited to a particular shape of the finger sleeve 106. Further, as explained in conjunction with FIG. 3, in one embodiment of the present invention, the finger sleeve 106 includes two half portions hingedly connected to each other.

The finger sleeve 106 may be configured to accommodate any finger, such as an index finger, a middle finger, a ring finger, a little finger or a thumb, of the user. Further, the finger sleeve 106 is configured to accommodate a wide range of finger shapes and sizes. Furthermore, the finger sleeve 106 is configured to accommodate any finger of a left hand or a right hand of the user. Still further, the finger sleeve 106 is ergonomically shaped so that movement of the finger joints is not inhibited. In one embodiment of the present invention, the finger sleeve 106 may be configured to accommodate a portion of the finger of the user. In one embodiment of the present invention, the finger sleeve 106 may be about two to three inches long. Further, in one embodiment of the present invention, the finger sleeve 106 may be composed of an expandable non-slip foam material. In another embodiment of the present invention, the finger sleeve 106 may be composed of any other expandable materials known to the person having ordinary skill in the art. The finger sleeve 106 is configured to accommodate the first switch 108.

More specifically, the first switch 108 is disposed on the bottom portion 126 of the finger sleeve 106. The first switch 108 is configured to function similar to a left click button of a conventional pointing device (generally referred to as “computer mouse”) of a computer. For example, the first switch 108 is configured to allow a user to interact with the electronic device, similar to a graphical user interface (GUI). For example, the first switch 108 is configured to trigger the action such as cursor movement, text highlighting, “drag and drop”, double clicking and the like.

The second switch 110 is disposed on the first side portion 128 of the finger sleeve 106. In one embodiment of the present invention, the second switch 110 may be disposed on the second side portion 128 of the finger sleeve 106. In one embodiment of the present invention, the second switch 110 may be configured to function similar to a right click button of the conventional pointing device of the computer. The second switch 110 may be activated by a thumb of the user. The second switch 110 and the first switch 108 are functionally coupled to the optical means 112.

The optical means 112 is disposed on the finger sleeve 106. In one embodiment of the present invention, the optical means 112 is disposed on the bottom portion 126 of the finger sleeve 106. The optical means 112 is configured to detect movement of the finger sleeve 106 relative to an underlying surface. In one embodiment of the present invention, the optical means 112 includes a light emitting diode and a photo diode, similar to an optical mouse known in the art. The optical means 112 is configured to control x-y positioning of a cursor of the electronic device on a screen of the electronic device in response to the movement of the finger sleeve 106 relative to the underlying surface. The optical means 112 is functionally coupled to the central processing unit 114.

The central processing unit 114 is disposed on the finger sleeve 106. The central processing unit 114 is disposed on the top portion 124 of the finger sleeve 106. In one embodiment of the present invention, the central processing unit 114 may be disposed on the bottom portion 126, the first side portion 128 or the second side portion 130 of the finger sleeve 106. The central processing unit 114 is electronically coupled to the first switch 108, the second switch 110 and the optical means 112. In one embodiment of the present invention, the central processing unit 114 is electronically coupled to the first switch 108, the second switch 110 and the optical means 112 by means of semiconductors. In another embodiment of the present invention, the central processing unit 114 may be electronically coupled to the first switch 108, the second switch 110 and the optical means 112 by means of means of various other electronic means known to the person having ordinary skill in the art. The central processing unit 114 is configured to generate a spatial data of the movement of the finger sleeve 106 relative to the underlying surface. The central processing unit 114 may be configured to have a user programmable software capability to allow the user to configure the input apparatus 100 as per his/her personal requirements. The central processing unit 114 may be functionally coupled to the transmitter 116.

The transmitter 116 is disposed on the finger sleeve 106. The transmitter 116 may be disposed on the top portion 124, the bottom portion 126, the first side portion 128 or the second side portion 130 of the finger sleeve 106. The transmitter 116 is configured to wirelessly transmit the spatial data to the receiver module 104. In one embodiment of the present invention, the transmitter may include a USB (Universal Serial Bus) antenna. In another embodiment of the present invention, the transmitter 116 may be any other transmitter known to the person having ordinary skill in the art and capable of being wirelessly transmitting the spatial data to the receiver module 104. Accordingly, the present invention is not limited to the type of transmitter used. The transmitter 116 is functionally coupled to the battery 118. The battery 118 is disposed on the top portion 124 of the finger sleeve 106. The battery 118 may also be disposed on the bottom portion 126, the first side portion 128 or the second side portion 130 of the finger sleeve 106. The battery 118 is functionally coupled to the first switch 108, the second switch 110, the optical means 112, the central processing unit 114 and the transmitter 116. In one embodiment of the present invention, the battery 118 may be functionally coupled to the first switch 108, the second switch 110, the optical means 112, the central processing unit 114 and the transmitter 116 by means of various electrical and/or electronic means known to the person having ordinary skill in the art. The electric means may include electric wires and the electronic means may include semiconductors. In another embodiment of the present invention, the battery 118 may be functionally coupled to the first switch 108, the second switch 110, the optical means 112, the central processing unit 114 and the transmitter 116 by means of by any other means known to the person having ordinary skill in the art. In one embodiment of the present invention, the battery 118 is a lithium battery. In another embodiment of the present invention, the battery 118 may be a rechargeable battery. In yet another embodiment of the present invention, the battery 118 may be any other battery known to the person having ordinary skill in the art.

Further, in one embodiment of the present invention, the optical wireless pointing device 102 may include an on/off button (not shown) disposed on the finger sleeve 106 for allowing the user to easily turn the input apparatus 100 on or off as per the user requirement. The optical wireless pointing device 102 is wirelessly connected to the receiver module 104.

The receiver module 104 is adapted to receive the spatial data wirelessly transmitted by the transmitter 116 of the optical pointing device 102. The receiver module 104 is configured to be electronically coupled to the electronic device. Further, the receiver module 104 is configured to direct the spatial data to the electronic device. More specifically, in one embodiment of the present invention, the receiver module 104 is configured to direct the spatial data to the electronic device by means of a control function mechanism of the electronic device. In one embodiment of the present invention, the receiver module 104 may be incorporated into a USB drive. Further, the USB drive may be electronically connected to the electronic device. The USB drive may be electronically connected to the electronic device by means of the USB port configured on the electronic device. Further, in another embodiment of the present invention, the receiver module 104 is configured to direct the spatial data to the electronic device by various other means known to the person having ordinary skill in the art.

Now referring to FIG. 3, a perspective view of a finger sleeve 134 of the optical wireless pointing device 102 is disclosed, in accordance with another embodiment of the present invention. The finger sleeve 134 includes two half portions, such as a first half portion 136 and a second half portion 138 hingedly connected to the first half portion 136. Each of the first half portion 136 and the second half portion 138 are configured to have a semi cylindrical shape. In one embodiment of the present invention each of the first half portion 136 and the second half portion 138 is configured to have any other shape. Accordingly the present invention is not limited to a particular shape of the first half portion 136 and the second half portion 138.

In one embodiment of the present invention, the second half portion 138 is hingedly connected to the first half portion 136 by means of a hinge mechanism (not shown). The hinge mechanism may be selected from various hinge mechanism known to the person having ordinary skill in the art. The first switch 108, the optical means 112 and the battery 118 may be disposed on the first half portion 136. More specifically, the first switch 108 (shown in FIG. 2B) and the optical means 112 (shown in FIG. 1) may be disposed on a bottom portion (not shown) of the first half portion 136 and the battery 118 may be disposed on a first side portion 140 of the first half portion 136. Furthermore, the second switch 110, the central processing unit 114 and the transmitter 116 (shown in FIG. 1) may be disposed on the second half portion 138. More specifically, the second switch 110 may be disposed on a first side portion 142 of the second half portion 138 and the central processing unit 114 and the transmitter 116 may be disposed on a top portion 144 of the second half portion 138.

Now referring to FIG. 4, a perspective view of the input apparatus 100 for an electronic device 200 in an operative position of the input apparatus 100 is disclosed, in accordance with an embodiment of the present invention. The electronic device 200 is a computer. The electronic device 200 includes a monitor 202, a central processing unit 204 and a keyboard 206. The central processing unit 204 includes a USB port 208. The optical wireless pointing device 102, more specifically the finger sleeve 106, of the input apparatus 100 is received on an index finger 302 of a hand 304 of a user (not shown). The receiver module 104 (shown in FIG. 1) of the input apparatus 100 is incorporated into a USB drive 306. The USB drive 306 is electronically connected to the USB port 208 of the electronic device 200.

In use, the user may input the spatial data into the electronic device 200 by the movement of the optical wireless pointing device 102, more specifically by movement of the finger sleeve 106 of the optical wireless pointing device 102, of the input apparatus 100 relative to an underlying surface 308. Moreover, movements of the optical wireless pointing device 102 are replicated on the monitor 202 of the electronic device 200 by movements of a cursor (not shown) and other visual changes. The underlying surface 308 may be a table top, a mouse pad, an arm rest of a chair and the like. More specifically, the underlying surface 308 may be any surface capable of reflecting light. For triggering an action, such as cursor movement, text highlighting, “drag and drop”, double clicking and the like, in the electronic device 200 the user may activate the first switch 108 disposed on the bottom portion 126 of the finger sleeve 106 (referring to FIG. 1 and FIG. 2B). Further, for triggering an action similar to a right click button of the conventional pointing device of the computer, the second switch 110 may be activated by the user.

Various embodiments of the present invention offer following advantages. The input device, as described herein, is capable of preventing tenderness and Carpel Tunnel Syndrome in a hand of a user. Further, the input device is configured to have an ergonomic design. Still further, the input device is simple in construction and easy to use. Furthermore, the input device of the present invention is user friendly and easy to operate. Moreover, the input device is capable of quickly and easily attached to a finger of the user or removed from a finger of a user.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The embodiments were chosen and described in order to best explain the principles of the present invention and its practical application, and to thereby enable others skilled in the art to best utilize the present invention and various embodiments with various modifications as are suited to the particular use contemplated. It is understood that various omissions and substitutions of equivalents are contemplated as circumstances may suggest or render expedient, but such omissions and substitutions are intended to cover the application or implementation without departing from the spirit or scope of the claims of the present invention.

What is claimed is:

1. An input apparatus for an electronic device, the input apparatus comprising:
an optical wireless pointing device, the optical wireless pointing device comprising,
a finger sleeve configured to accommodate a finger of a user, the finger sleeve adapted to be moved relative to an underlying surface;
a first switch disposed on a bottom portion of the finger sleeve;
a second switch disposed on a side portion of the finger sleeve;
an optical means configured on the finger sleeve, the optical means configured to detect movement of the finger sleeve relative to the underlying surface;
a central processing unit disposed on the finger sleeve, the central processing unit electronically coupled to the first switch, the second switch and the optical means, the central processing unit configured to generate a spatial data based on the movement of the finger sleeve detected by the optical means;
a transmitter functionally coupled to the central processing unit, the transmitter configured to wirelessly transmit the spatial data; and
a battery disposed on the finger sleeve, the battery functionally coupled to the first switch, the second switch, the optical means, the central processing unit and the transmitter; and
a receiver module electronically coupled to the electronic device, the receiver module adapted to receive the spatial data wirelessly transmitted by the transmitter and direct the spatial data to the electronic device.

2. The input device of claim 1, wherein the finger sleeve comprising two half portions hingedly connected to each other.

3. The input device of claim 1, wherein the battery is a lithium battery.

4. The input device of claim 1, wherein the finger sleeve is configured to accommodate a wide range of finger shapes and sizes.
